(19) United States
(12) Patent Application Publication
(10) Pub. No.: US 2025/0017081 A1
(43) Pub. Date: Jan. 9, 2025

(54) DISPLAY DEVICE AND METHOD FOR MANUFACTURING THE SAME

(71) Applicant: Samsung Display Co., LTD., Yongin-si (KR)

(72) Inventors: JIN-HEE BAE, Yongin-si (KR); HYUNWOO LEE, Yongin-si (KR); WOOSUK JANG, Yongin-si (KR)

(21) Appl. No.: 18/645,439

(22) Filed: Apr. 25, 2024

(30) Foreign Application Priority Data
Jul. 7, 2023 (KR) 10-2023-0088092

(51) Int. Cl. H10K 59/80; B32B 5/02; B32B 15/04; B32B 17/10; B32B 37/24; G06F 3/041; H01L 33/56; H10K 71/50

(52) U.S. Cl. CPC H10K 59/873; B32B 5/02; B32B 15/04; B32B 17/10; B32B 37/24; H01L 33/56; H10K 71/50; B32B 2037/243; B32B 2255/26; B32B 2255/28; B32B 2260/021; B32B 2260/046; B32B 2457/20; G06F 3/041; H01L 2933/005

(57) ABSTRACT

A display device includes a display panel in which a first region, a second region, and a third region are defined along a first direction, a window module disposed on the display panel, and including a window substrate, a coating member covering a side surface of the display panel and a side surface of the window module, and a lower substrate disposed under the display panel. A side surface of the window substrate is disposed more inwardly than the side surface of the display panel is, and a side surface of the coating member is connected to the lower substrate.

This application claims priority to Korean Patent Application No. 10-2023-0088092, filed on Jul. 7, 2023, and all the benefits accruing therefrom under 35 U.S.C. § 119, the content of which in its entirety is herein incorporated by reference.

### BACKGROUND

### 1. Field

The disclosure herein relates to a display device that reduces defects caused by foreign matters and improves impact resistance, and a method for manufacturing the same.

### 2. Description of the Related Art

A display device, that supplies a user with an image, such as a television, a monitor, a smartphone, a tablet computer, etc., includes a display panel that displays the image. As the display panel, various display panels such as a liquid crystal display panel, an organic light-emitting display panel, an electro-wetting display panel, and an electrophoretic display panel are being developed. Recently, in response to a market demand, research on solving a display panel defect caused by foreign matters penetrating into a display panel, and research on a display device with improved impact resistance are being conducted.

### SUMMARY

The disclosure provides a display device that reduces defects caused by foreign matters and improves impact resistance.

The disclosure also provides a method for manufacturing a display device that reduces defects caused by foreign matters and improves impact resistance.

An embodiment of the invention provides a display device including a display panel in which a first region, a second region, and a third region are defined along a first direction, a window module disposed on the display panel, and including a window substrate, a coating member covering a side surface of the display panel and a side surface of the window module, and a lower substrate disposed under the display panel, where a side surface of the window substrate is disposed more inwardly than the side surface of the display panel is, and a side surface of the coating member is connected to the lower substrate.

In an embodiment, the coating member may include a resin material and a plurality of particles.

In an embodiment, the resin material may include urethane.

In an embodiment, the resin material may include acrylic.

In an embodiment, the display panel may include a first side surface, a second side surface, a third side surface, and a fourth side surface, the first side surface, the second side surface, and the fourth side surface are coupled to the coating member, and a region adjacent to the third side surface is bent.

In an embodiment, the first side surface and the third side surface may be spaced apart from each other in the first direction and extend in a second direction crossing the first direction, and the second side surface and the fourth side surface may be spaced apart from each other in the second direction and extend in the first direction.

In an embodiment, a step region defined by the side surface of the display panel and the side surface of the window module may be filled with the coating member.

In an embodiment, the window module may further include a window protection layer, a light-blocking pattern, and a functional layer.

In an embodiment of the invention, a display device includes a display panel, a window module disposed on the display panel, a coating member which fills a step region defined by a side surface of the display panel and a side surface of the window module, and a lower substrate disposed under the display panel.

In an embodiment, the coating member may cover the side surface of the display panel and the side surface of the window module.

In an embodiment, a first region, a second region, and a third region may be defined in the display panel along a first direction, the side surface of the window module may be partially disposed more inwardly than the side surface of the display panel is, and a side surface of the coating member may be connected to the lower substrate.

In an embodiment, the display panel may include a first side surface extending in a second direction crossing the first direction, a second side surface extending from the first side surface in the first direction, a third side surface extending from the second side surface in a direction parallel to the second direction, and a fourth side surface extending from the third side surface in a direction parallel to the first direction, the first side surface, the second side surface, and the fourth side surface may be coupled to the coating member, and a region adjacent to the third side surface may be bent.

In an embodiment, the coating member may include a resin material and a plurality of particles.

In an embodiment, the resin material may include at least one selected from urethane and acrylic.

In an embodiment of the invention, a method for manufacturing a display device includes preparing a preliminary display device including a display panel and a window module, filling, with a coating solution, a step region defined by a side surface of the display panel and a side surface of the window module, and coupling the preliminary display device to a lower substrate.

In an embodiment, the display panel may include a first side surface extending in s second direction crossing a first direction, a second side surface extending from the first side surface in the first direction, a third side surface extending from the second side surface in a direction parallel to the second direction, and a fourth side surface extending from the third side surface in a direction parallel to the first direction, and the filling of the step region with the coating solution may include applying a coating member to be in contact with the first side surface, the second side surface, and the fourth side surface of the display panel.

In an embodiment, the coating solution may include a resin material and a plurality of particles, and the resin material may include at least one selected from urethane and acrylic.

In an embodiment, the filling the step region with the coating solution may include performing a gravure coating.

In an embodiment, the filling the step region with the coating solution may include performing a pad printing.

In an embodiment, the filling the step region with the coating solution may include performing an electro-hydro-dynamic printing.

### BRIEF DESCRIPTION OF THE DRAWINGS

The above and other features of the invention will become more apparent by describing in further detail embodiments thereof with reference to the accompanying drawings, in which:

FIG. 1A is a perspective view of a display device according to an embodiment of the invention in an unfolded state;

FIG. 1B is a perspective view illustrating a folding operation of a display device according to an embodiment of the invention;

FIG. 1C is a plan view of a display device according to an embodiment of the invention in a folded state;

FIG. 1D is a perspective view illustrating a folding operation of a display device according to an embodiment of the invention;

FIG. 2 is a cross-sectional view of a display device taken along line I-I′ in FIG. 1A;

FIG. 3 is a plan view of a display panel according to an embodiment of the invention; and

FIGS. 4 to 6 are cross-sectional views illustrating some of a method for manufacturing a display device according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

In this specification, when a component (or region, layer, portion, etc.) is referred to as “on”, “connected”, or “coupled” to another component, it means that it is placed/connected/coupled directly on the other component or a third component can be disposed between them.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

Terms such as first and second may be used to describe various components, but the components should not be limited by the terms. These terms are only used for the purpose of distinguishing one component from other components. For example, without departing from the scope of the invention, a first component may be referred to as a second component, and similarly, a second component may be referred to as a first component. Singular expressions include plural expressions unless the context clearly indicates otherwise.

In addition, terms such as “below”, “lower”, “above”, and “upper” are used to describe the relationship between components shown in the drawings. The terms are relative concepts and are described based on the directions indicated in the drawings.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used in this specification have the same meaning as commonly understood by one of ordinary skill in the art to which this invention belongs. In addition, terms such as terms defined in commonly used dictionaries should be interpreted as having a meaning consistent with the meaning having in the context of the related technology, and should not be interpreted as too ideal or too formal unless explicitly defined here.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the inventions will be described with reference to the drawings.

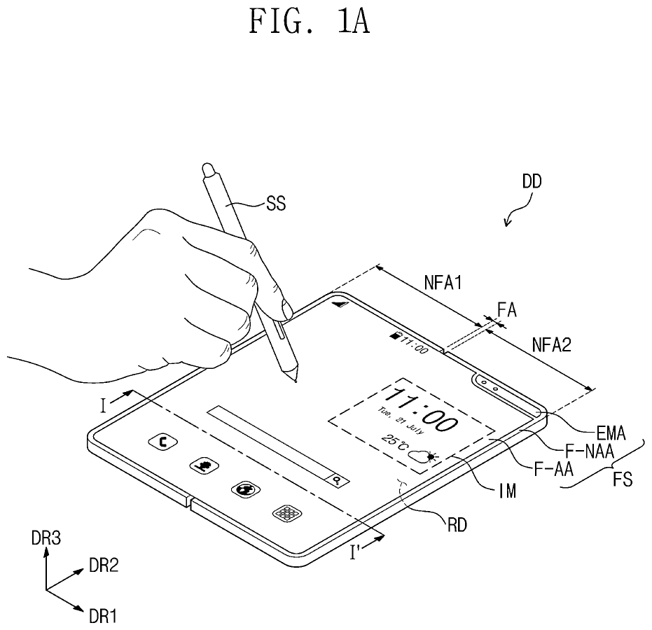

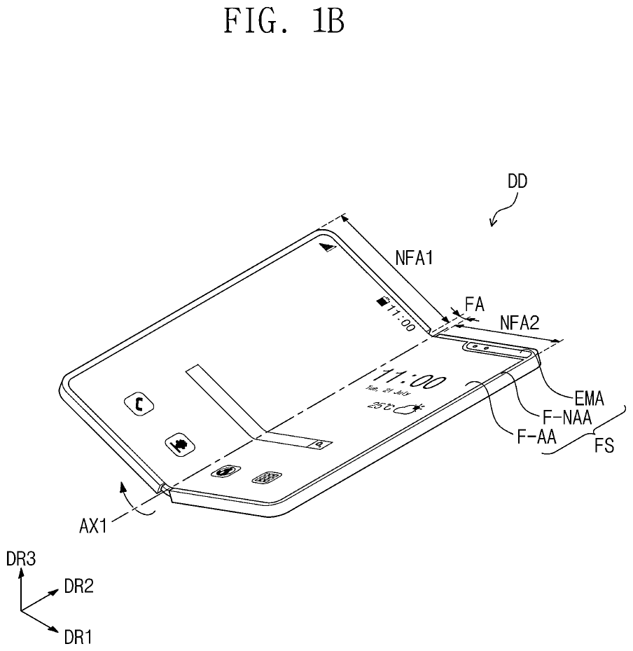

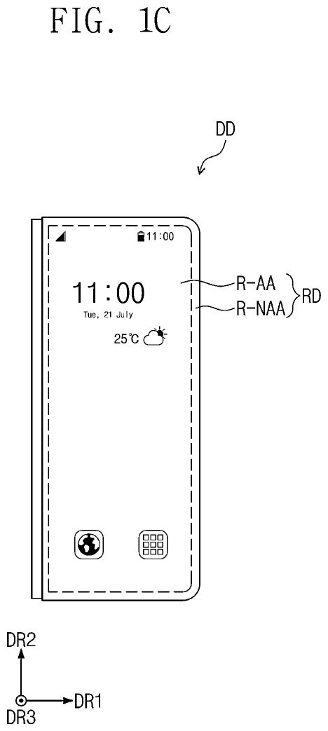

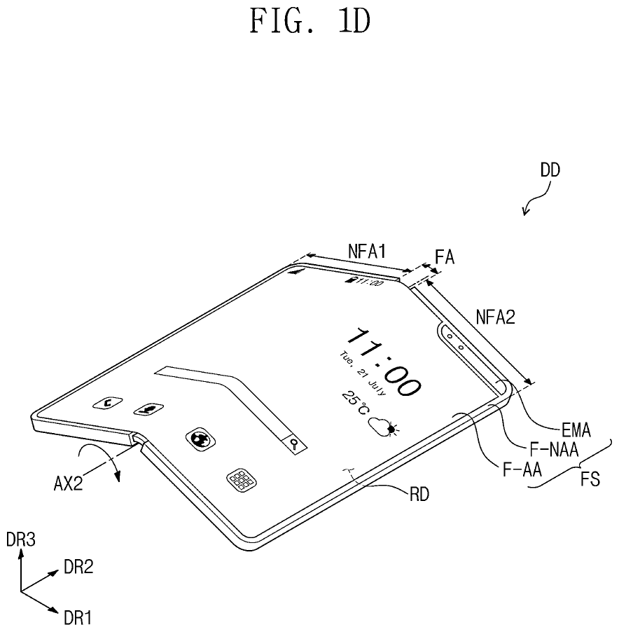

FIG. 1A is a perspective view of a display device DD according to an embodiment of the invention in an unfolded state.

Referring to FIG. 1A, an embodiment of the display device DD may be a device activated in response to an electrical signal. Embodiments of the display device DD may include various types of electronic device including a display screen. In an embodiment, for example, the display device DD may include a tablet computer, a notebook computer, a computer, a smart television, or the like. In an embodiment, the display device DD may be a smartphone, for example, as shown in the drawings.

The display device DD may display an image IM toward a third direction DR3 on a first display surface FS parallel to each of a first direction DR1 and a second direction DR2. The first display surface FS on which the image IM is displayed may correspond to the front surface of the display device DD. The image IM may include a static image as well as a dynamic image. FIG. 1A illustrates, as an example of the image IM, an internet search window, a clock window, and a plurality of applications.

In embodiments of the invention, the upper surface (or front surface) and the lower surface (or rear surface) of each configuration are defined on the basis of a direction in which the image IM is displayed. The front surface and the rear surface may be opposed to each other in the third direction DR3, and a normal direction of each of the front surface and the rear surface may be parallel to the third direction DR3.

A distance between the front surface and the rear surface in the third direction DR3 may correspond to a thickness/height of the display device DD in the third direction DR3. Here, directions indicated by the first to third directions DR1, DR2, and DR3 are relative concepts, and may be changed to other directions.

The display device DD may sense an external input applied to the display device DD. The external input may include various types of inputs supplied from the outside of the display device DD. For example, the external input may include not only a touch by a part of a body such as a user's hand, but also an external input (for example, hovering) applied to the display device DD in proximity or applied to the display device DD while being adjacent within a predetermined distance. The external input may have various forms such as force, pressure, temperature, or light.

FIG. 1A illustrates a case where the external is input through a pen SS of a user, as an example. Although not shown, in an embodiment, the pen SS may be attached to or detached from the inside or outside of the display device DD, and the display device DD may supply or receive a signal corresponding to attaching or detaching the pen SS.

The display device DD may include a first display surface FS and a second display surface RD. The first display surface FS may include a first active region F-AA, a first peripheral region F-NAA, and an electronic module region EMA. The second display surface RD may be defined as a surface opposed to at least a portion of the first display surface FS.

The first active region F-AA may be a region activated in response to an electrical signal. The first active region F-AA may be a region where the image IM may be displayed, and an input of the pen SS may be sensed.

The first peripheral region F-NAA may be adjacent to the first active region F-AA. The first peripheral region F-NAA may have a predetermined color. The first peripheral region F-NAA may surround the first active region F-AA. Accordingly, a shape of the first active region F-AA may be substantially defined by the first peripheral region F-NAA. However, this is illustrated as an example, and the first peripheral region F-NAA may be disposed adjacent to one side of the first active region F-AA, and may be omitted.

Various electronic modules may be disposed in the electronic module region EMA. In an embodiment, for example, the electronic modules may include at least one selected from a camera, a speaker, a light-sensing sensor, and a heat-sensing sensor. The electronic module region EMA may sense an external subject received through the display surfaces FS and RD, or may supply, to the outside, a sound signal such as a voice through the display surfaces FS and RD. The electronic module may include a plurality of configurations, and is not limited to any one embodiment.

The electronic module region EMA may be surrounded by the first peripheral region F-NAA. However, this is an example, and an embodiment of the invention is not limited thereto. In an embodiment, for example, the electronic module region EMA may be surrounded by the first active region F-AA and the first peripheral region F-NAA, be disposed in the first active region F-AA, and be omitted.

The display device DD according to an embodiment may include at least one folding region FA, and a plurality of non-folding regions NFA1 and NFA2 extending from the folding region FA. In an embodiment, for example, a first non-folding region NFA1, the folding region FA, and a second non-folding region NFA2 may be defined along the first direction DR1. In such an embodiment, the first non-folding region NFA1 may extend from the folding region FA along an opposite direction of the first direction DR1, and the second non-folding region NFA2 may extend from the folding region FA along the first direction DR1.

The folding region FA may be referred to as a foldable region, and the first and second non-folding regions NFA1 and NFA2 may be referred to as a non-foldable region. The folding region FA may be adjacent to the first non-folding region NFA1 and the second non-folding region NFA2, and may be folded along a folding axis AX1 or AX2 (see FIG. 1B or 1D).

FIG. 1B is a perspective view illustrating a folding operation of the display device DD according to an embodiment of the invention.

Referring to FIG. 1B, the display device DD according to an embodiment may be folded along a first folding axis AX1 extending in the second direction DR2. The display device DD may have a predetermined curvature and a predetermined radius of curvature in a folded state. The display device DD may be folded along the first folding axis AX1, so that the first non-folding region NFA1 and the second non-folding region NFA2 may face each other, and the display device DD may be changed to an in-folded state so as not to expose the first display surface FS to the outside.

FIG. 1C is a plan view of the display device DD according to an embodiment of the invention in a folded state.

Referring to FIG. 1C, the second display surface RD of the display device DD according to an embodiment may be viewed to a user in the in-folded state. In this case, the second display surface RD may include a second active region R-AA that displays an image. The second active region R-AA may be a region activated in response to an electrical signal. The second active region R-AA may be a region that displays an image, and senses an external input having various forms.

A second peripheral region R-NAA may be adjacent to the second active region R-AA. The second peripheral region R-NAA may have a predetermined color. The second peripheral region R-NAA may surround the second active region R-AA. In addition, although not shown, the second display surface RD may further include an electronic module region in which an electronic module including various configurations is disposed, and is not limited to any one embodiment.

FIG. 1D is a perspective view illustrating a folding operation of the display device DD according to an embodiment of the invention.

Referring to FIG. 1D, the display device DD according to an embodiment may be folded along a second folding axis AX2 extending in the second direction DR2. The display device DD may be folded along the second folding axis AX2, and thus may be changed to an out-folded state so as to expose the first display surface FS to the outside. In an embodiment of the invention, the display device DD may be configured to mutually repeat an in-folding operation or an out-folding operation from an unfolding operation, but an embodiment of the invention is not limited thereto.

FIGS. 1A to 1D illustrate embodiment which are foldable along one folding axis AX1 or AX2, but the number of a folding axis and the number of a non-folding region according to the folding axis are not limited thereto. In an embodiment, for example, the display device DD may be folded along a plurality of folding axes, and thus the first display surface FS and the second display surface RD may partially face each other.

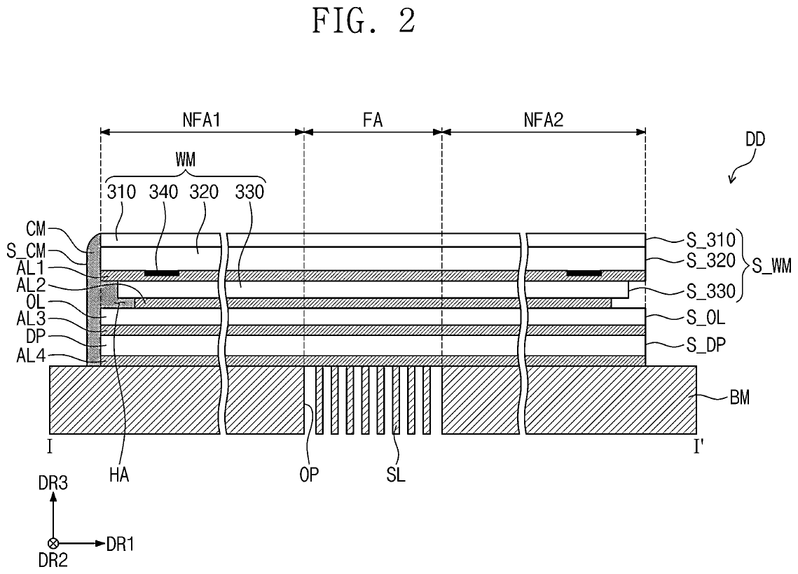

FIG. 2 is a cross-sectional view of a display device DD taken along line I-I′ in FIG. 1A.

Referring to FIG. 2, an embodiment of the display device DD may include a window module WM, an optical film OL, a display panel DP, a lower substrate BM, and a coating member CM. In addition, the display device DD may further include adhesive layers AL1, AL2, AL3, and AL4 that bond elements of the display device DD to each other.

The adhesive layers AL1, AL2, AL3, and AL4 described hereinafter may be transparent adhesive layers including at least one selected from a pressure sensitive adhesive film (PSA), an optically clear adhesive film (OCA), and an optically clear resin (OCR). In an embodiment, at least one adhesive layer selected from the adhesive layers AL1, AL2, AL3, and AL4 may be omitted.

The window module WM may be disposed on the display panel DP. The window module WM may be coupled to a housing (not shown) to define an exterior, and may protect the display panel DP. The window module WM may include a window substrate 330, a window protection layer 320, and a light-blocking pattern 340.

The window substrate 330 may include a material having a high transmittance. In an embodiment, the window substrate 330 may be chemically reinforced glass. In such an embodiment, even if folding and unfolding operations are repeatedly performed, the window substrate 330 may minimize generation of a wrinkle therein.

The window protection layer 320 may be disposed on the window substrate 330. The window protection layer 320 and the window substrate 330 may be coupled to each other by a first adhesive layer AL1. The window protection layer 320 may include a plastic film. In an embodiment, for example, the window protection layer 320 may include at least one selected from polyimide, polycarbonate, polyamide, triacetylcellulose, polymethylmethacrylate, and polyethylene terephthalate.

In an embodiment, the light-blocking pattern 340 may be disposed on a lower surface of the window protection layer 320. In an embodiment, the light-blocking pattern 340 may be disposed on one surface, of the window protection layer 320, facing the window substrate 330. The first adhesive layer AL1 may cover the light-blocking pattern 340, but an embodiment of the invention is not limited thereto.

The light-blocking pattern 340 is a colored light-blocking film, and may be formed, for example, in a coating method. The light-blocking pattern 340 may include a base material, and a pigment or dye mixed in the base material. Accordingly, a user may recognize a first peripheral region F-NAA (see FIG. 1A) of the display device DD by a predetermined color of the light-blocking pattern 340. That is, the light-blocking pattern 340 may overlap the first peripheral region F-NAA.

FIG. 2 illustrates an embodiment where the light-blocking pattern 340 is disposed inside the window protection layer 320 with a predetermined distance from the end of the window protection layer 320, but an embodiment of the invention is not limited thereto. In an embodiment, the light-blocking pattern 340 may be disposed under the window protection layer 320 to align with the end of the window protection layer 320, and is not limited to any one embodiment. In addition, FIG. 2 illustrates, as an example, an embodiment where the light-blocking pattern 340 is disposed on the lower surface of the window protection layer 320, but an embodiment of the invention is not limited thereto. in an embodiment, for example, the light-blocking pattern 340 may be disposed on the upper surface of the window protection layer 320, or the upper surface or the lower surface of the window substrate 330.

The window module WM may further include a functional layer 310. The functional layer 310 may be disposed on the window protection layer 320 as the outermost layer of the window module WM. The functional layer 310 may be a functional layer for improving use characteristics of the display device DD, and may be applied on the window protection layer 320 and be supplied. Anti-fingerprint characteristics, anti-pollution characteristics, anti-reflective characteristics, anti-scratch characteristics, or the like may be improved by the functional layer 310. In an embodiment, for example, the functional layer 310 may be a hard-coating layer.

The optical film OL may be disposed under the window module WM. The optical film OL and the window module WM may be coupled to each other by a second adhesive layer AL2. The optical film OL may reduce reflectance of the display panel DP for light incident on the display panel DP. Although not shown, the optical film OL may further include at least one selected from an anti-reflective film, a polarizing film, a color filter, and a grey filter.

The display panel DP may be disposed under the optical film OL. The display panel DP and the optical film OL may be coupled by a third adhesive layer AL3. The display panel DP may have a function of an output unit that displays an image, and a function of an input unit that senses an input applied from the outside. In an embodiment, for example, the display panel DP may include a display layer and a sensor layer. The display layer may be a configuration that substantially generates an image. The display layer may be an organic light-emitting display panel, a quantum-dot display panel, or an inorganic light-emitting display panel, for example, but is not specially limited thereto.

The lower substrate BM may be disposed under the display panel DP. The lower substrate BM and the display panel DP may be coupled to each other by a fourth adhesive layer AL4. The lower substrate BM may support configurations disposed on the lower substrate BM, and maintain an unfolded state and a folded state of the configurations disposed thereon. In addition, a thermal performance of the display device DD may be improved by the lower substrate BM.

The lower substrate BM may protect the display panel DP. In an embodiment, for example, when the display device DD is folded, the lower substrate BM may reduce a stress applied to the display panel DP. In addition, the lower substrate BM may effectively prevent foreign moisture from penetrating the display panel DP, and absorb an external impact.

A plurality of openings OP may be defined in a region, of the lower substrate BM, overlapping the folding region FA. The plurality of openings OP may be formed by being extending from the upper surface to the rear surface of the lower substrate BM. Portions between the plurality of openings OP in the folding region FA may have a slit SL structure. The slit SL structure may have a shape in which the plurality of openings OP are connected to each other like a mesh.

According to an embodiment of the invention, when the display device DD is in-folded along the first folding axis AX1 (see FIG. 1B), an area of each of the plurality of opening OP between the slits SL may increase or decrease in response to a folding direction, and when the display device DD is not folded, the plurality of openings OP may return to an original shape. Accordingly, since the plurality of openings OP are formed in a region overlapping the folding region FA, when the display device DD is folded, the lower substrate BM may change a shape thereof more easily.

The lower substrate BM may include at least one selected from stainless steel, titanium, and a fiber reinforced composite. The fiber reinforced composite may be a carbon fiber reinforced plastic (CFRP), or a glass fiber reinforced plastic (GFRP).

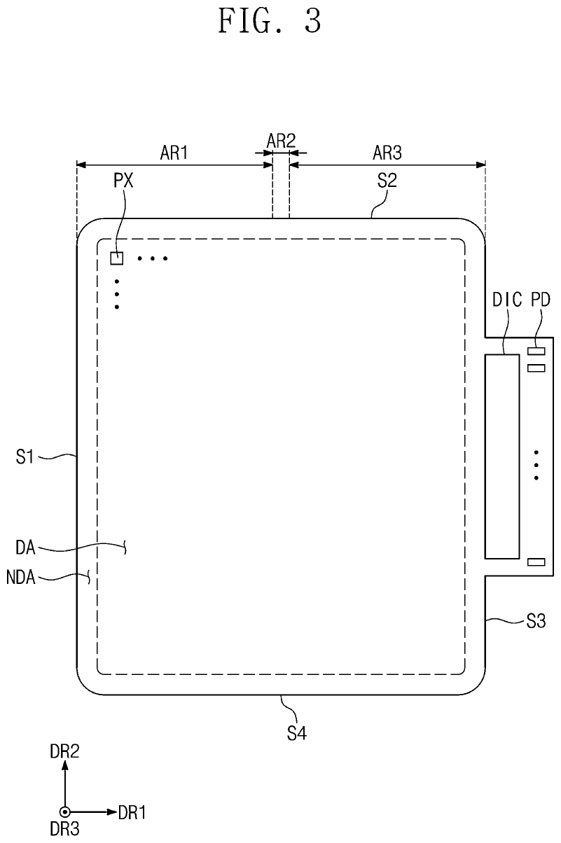

In an embodiment, a side surface S_330 of the window substrate 330 may be nearer to a second region AR2 (see FIG. 3) than a side surface S_DP of the display panel DP is. That is, the side surface S_330 of the window substrate 330 may be disposed more inwardly than the side surface S_DP of the display panel DP is. The coating member CM may continuously cover the side surface S_DP of the display panel DP and a side surface S_WM of the window module WM. In an embodiment, the coating member CM may continuously cover the side surface S_WM of the window module WM, a side surface S_OL of the optical film OL, the side surface S_DP of the display panel DP, and side surfaces of the adhesive layers AL1, AL2, AL3, and AL4. A step region HA may be defined by the side surface S_DP of the display panel DP (or the side surface S_OL of the optical film OL) and the side surface S_WM of the window module WM (or a side surface of the second adhesive layer AL2). The step region HA may be filled with the coating member CM. A side surface S_CM of the coating member CM may be connected to the lower substrate BM.

According to an embodiment of the invention, since the coating member CM is applied onto a partial side surface of the display device DD, a step formed on a side surface of the display device DD may be compensated. In such an embodiment, a coupling force between the window module WM, the optical film OL, and the display panel DP which form the display device DD may be improved, foreign matters may be blocked from being introduced inside the display device DD, and anti-scratch characteristics and impact resistance characteristics of the display device DD may be improved.

In an embodiment, the coating member CM may be a leather section finishing material for increasing durability of a leather section. The coating member CM may include a resin material and a plurality of particles. In an embodiment, the resin material of the coating member CM may include urethane. In another embodiment, the resin material of the coating member CM may include acrylic. In an embodiment, for example, the coating member CM may include at least one selected from purified water, silica gel, 1,2-benzisothiazol-3 (2H)-one, and titanium dioxide.

According to an embodiment of the invention, since the coating member CM includes the leather section finishing material, flexibility of the coating member CM may be increased. Accordingly, even when a folding operation of the display device DD is repeated, separation of the coating member CM from the side surface of the display device DD may be reduced or removed, and a discolor phenomenon of the side surface of the display device DD may be reduced or removed.

FIG. 3 is a plan view of a display panel DP according to an embodiment of the invention.

Referring to FIG. 3, the display panel DP may include a display region DA and a non-display region NDA. The display region DA of the display panel DP may correspond to the first active region F-AA (see FIG. 1A) of the first display surface FS (see FIG. 1A), or the second active region R-AA (see FIG. 1C) of the second display surface RD (see FIG. 1C). The non-display region NDA of the display panel DP may correspond to the first peripheral region F-NAA (see FIG. 1A) of the first display surface FS, or the second peripheral region R-NAA (see FIG. 1C) of the second display surface RD.

In addition, a first region AR1, a second region AR2, and a third region AR3 may be defined in the display panel DP along the first direction DR1. The first region AR1, the second region AR2, and the third region AR3 defined in the display panel DP may respectively correspond to the first non-folding region NFA1, the folding region FA, and the second non-folding region NFA2 of the display device DD (see FIG. 1A) described in FIG. 1A.

The display panel DP may include pixels PX, a driving chip DIC, and pads PD.

Each of the pixels PX may include a pixel driving circuit including a light-emitting element, a plurality of transistors (for example, a switching transistor, a driving transistor, etc.) connected to the light-emitting element, and a capacitor. Each of the pixels PX may emit light in response to an electrical signal applied thereto. The pixels PX may be disposed in the display region DA. However, this is an example, and some of configurations of the pixels PX may include a thin-film transistor disposed in the non-display region NDA, and is not limited to any one embodiment.

The pixels PX may be supplied with data voltages in response to a scan signal. The pixels PX may display an image by emitting light having luminance corresponding to the data voltages in response to light-emitting signals. A time duration for which the pixels PX emit light may be controlled by the light-emitting signals. Accordingly, the display panel DP may output an image through the display region DA by the pixels PX.

The driving chip DIC may be disposed in the non-display region NDA of the display panel DP. The non-display region NDA of the display panel DP may be at least partially bent. In an embodiment, for example, a portion of the display panel DP may be bent so that a portion of the non-display region NDA in which the driving chip DIC is disposed overlaps, on a plane, a portion of the display panel DP in which the display region DA is defined, but an embodiment of the invention is not limited thereto. The driving chip DIC may be mounted on a separate flexible circuit board, and the flexible circuit board may be bent to be connected to one end of the display panel DP. Accordingly, a bezel area of the display device DD (see FIG. 1A) may be reduced.

The pads PD may be disposed adjacent to one side surface of the non-display region NDA. The pads PD may be disposed more adjacent to the one side surface of the display panel DP than the driving chip DIC. The pads PD may be arranged along the second direction DR2. The display device DD may include a timing controller for controlling operations of a scan driver, a data driver, and a light emission driver, and a circuit board including a voltage generation portion for generating a voltage, and the pads PD may be portions to which a circuit board of the display device DD is connected.

The display panel DP may include a first side surface S1, a second side surface S2, a third side surface S3, and a fourth side surface S4. The first side surface S1 and the third side surface S3 may each extend in the second direction DR2, and may be apart from (or opposite to) each other in the first direction DR1. The second side surface S2 and the fourth side surface S4 may each extend in the first direction DR1, and may be apart from (or opposite to) each other in the second direction DR2. That is, the first side surface S1 may extend in the second direction DR2, and the second side surface S2 may extend from the first side surface S1 in the first direction DR1. The third side surface S3 may extend from the second side surface S2 in a direction parallel to the second direction DR2 (for example, an opposite direction of the second direction DR2), and the fourth side surface S4 may extend from the third side surface S3 in a direction parallel to the first direction DR1 (for example, an opposite direction of the first direction DR1). The fourth side surface S4 may be connected to the first side surface S1, and the first to fourth side surfaces S1, S2, S3, and S4 may respectively correspond to sides of a quadrilateral shape.

Referring to FIGS. 2 and 3, the coating member CM may be coupled to the first side surface S1, the second side surface S2, and the fourth side surface S4 of the display panel DP. The third side surface S3 is adjacent to the non-display region NDA in which the driving chip DIC is disposed, and a region adjacent to the third side surface S3 may be bent.

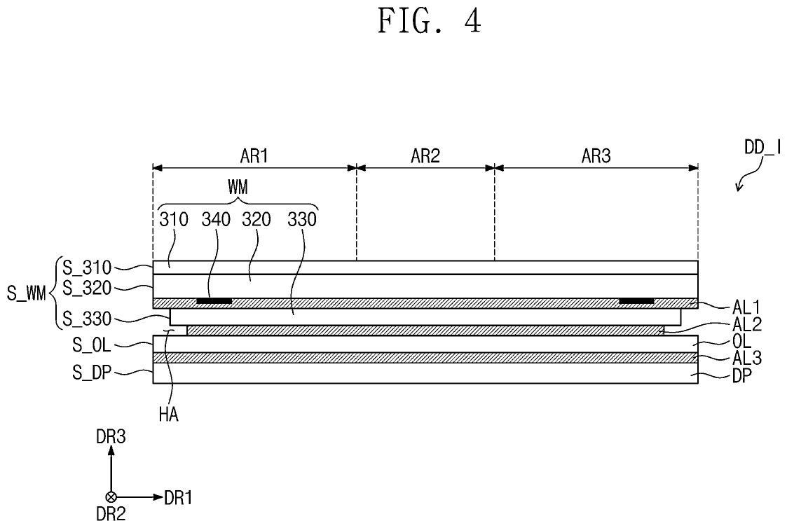

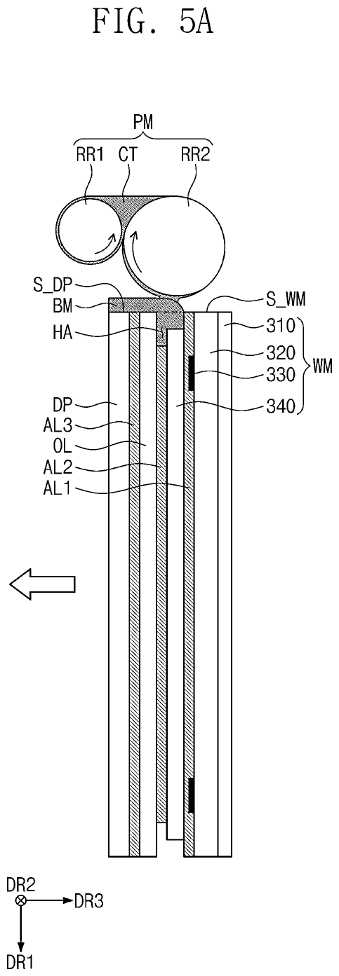

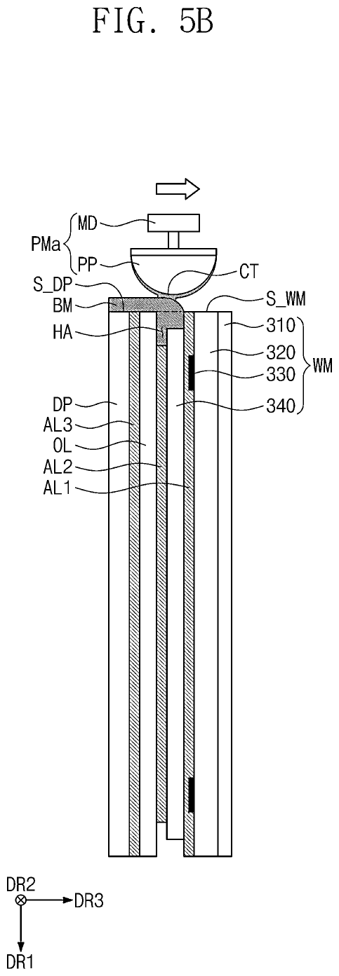

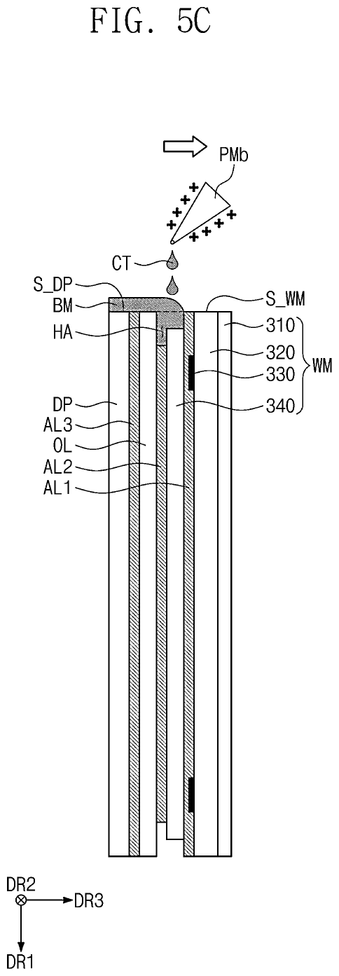

FIGS. 4 to 6 are cross-sectional views illustrating some operations of a method for manufacturing a display device according to an embodiment of the invention. In FIGS. 4 to 6, the same reference numerals or symbols are used for the same configurations as those described in FIGS. 1A to 3, and any repetitive detailed description thereof will be omitted. FIGS. 5A to 5C illustrate various embodiments of an operation of filling a coating solution.

The method for manufacturing a display device according to an embodiment of the invention may include an operation of preparing a preliminary display device including a display panel and a window module, an operation of filling, with a coating solution, a step region defined by a side surface of the display panel and a side surface of the window module, and an operation of coupling the preliminary display device and a lower substrate.

Referring to FIGS. 2 to 4, in the method for manufacturing a display device according to an embodiment of the invention, a preliminary display device DD_I may be prepared. The preliminary display device DD_I may include a display panel DP and a window module WM. In such an embodiment, the preliminary display device DD_I may include the window module WM, an optical film OL, the display panel DP, and adhesive layers AL1, AL2, and AL3. A side surface S_330 of the window substrate 330 may be nearer to the second region AR2 of the display panel DP corresponding to the folding region FA than a side surface S_DP of the display panel DP is.

The display panel DP may include the first side surface S1, the second side surface S2, the third side surface S3, and the fourth side surface S4. The first side surface S1 and the third side surface S3 may each extend in the second direction DR2, and may be apart from (or opposite to) each other in the first direction DR1. The second side surface S2 and the fourth side surface S4 may each extend in the first direction DR1, and may be apart from (or opposite to) each other in the second direction DR2. That is, the first side surface S1 may extend in the second direction DR2, and the second side surface S2 may extend from the first side surface S1 in the first direction DR1. The third side surface S3 may extend from the second side surface S2 in a direction parallel to the second direction DR2 (for example, an opposite direction of the second direction DR2), and the fourth side surface S4 may extend from the third side surface S3 in a direction parallel to the first direction DR1 (for example, an opposite direction of the first direction DR1). The fourth side surface S4 may be connected to the first side surface S1, and the first to fourth side surfaces S1, S2, S3, and S4 may respectively correspond to sides of a quadrilateral shape.

Thereafter, referring to FIGS. 5A to 5C, the method for manufacturing a display device according to an embodiment of the invention may include the operation of filling a step region HA with the coating solution CT. The step region HA may be defined by the side surface S_DP of the display panel DP (or a side surface of the optical film OL) and the side surface S_WM of the window module WM (or a side surface of the second adhesive layer AL2). That is, a coating device PM, PMa, or PMb may apply a side surface of the preliminary display device DD_I (see FIG. 4).

In an embodiment, the operation of filling with the coating solution CT may include an operation of applying the coating solution CT to be in contact with the first side surface S1 (see FIG. 3), the second side surface S2 (see FIG. 3), and the fourth side surface S4 (see FIG. 3) of the display panel DP. The coating solution CT may include a resin material and a plurality of particles. The resin material may include one of urethane and acrylic.

FIGS. 5A to 5C illustrate embodiments of an operation of applying the first side surface S1 (see FIG. 3) of the display panel DP. An operation of applying the second side surface S2 and the fourth side surface S4 of the display panel DP may be substantially the same as the operation of applying the first side surface S1 of the display panel DP. In addition, according to the above operation, three side surfaces of the preliminary display device DD_I adjacent to the first side surface S1, the second side surface S2, and the fourth side surface S4 of the display panel DP may be also applied.

Referring to FIG. 5A, an embodiment of the operation of filling with the coating solution CT may include performing a gravure coating. A coating device PM may include a first roller RR1, a second roller RR2, and the coating solution CT. The coating solution CT may be disposed between the first roller RR1 and the second roller RR2. The first roller RR1 may supply the second roller RR2 with an appropriate amount of the coating solution CT.

According to an embodiment where the operation of filling includes the gravure coating, the first roller RR1 may supply the second roller RR2 with the coating solution CT, and the coating solution CT put on the second roller RR2 may be applied onto the side surface of the preliminary display device DD_I (see FIG. 4) by rotating the second roller RR2. For example, the preliminary display device DD_I may move to the third direction DR3, and the second roller RR2 may rotate in a portion in contact with the preliminary display device DD_I in the same direction as the preliminary display device DD_I. That is, while rotating clockwise, the second roller RR2 may apply the coating solution CT. In this case, while rotating in an opposite direction of the second roller RR2, the first roller RR1 may supply an appropriate amount of the coating solution CT. The first roller RR1 may be referred to as a doctor roller, and the second roller RR2 may be referred to as a coating roller.

However, this is an example, and the gravure coating is not limited to the above embodiment. In an embodiment, for example, while rotating in an opposite direction of the preliminary display device DD_I, the first roller RR1 may apply the coating solution CT in the portion in contact with the preliminary display device DD_I.

The coating device PM may apply the side surface of the preliminary display device DD_I. In an embodiment, for example, while rotating clockwise, the second roller RR2 of the coating device PM may apply from the side surface S_DP of the display panel DP to the side surface S_WM of the window module WM. However, this is an example, and an embodiment of the invention is not limited thereto. In an embodiment, for example, while rotating counterclockwise, the second roller RR2 of the coating device PM may apply from the side surface S_WM of the window module WM to the side surface of the display panel DP.

Referring to FIG. 5B, an embodiment of the operation of filling with the coating solution CT may include performing a pad printing. A coating device PMa may include a pad part PP and a support part MD. The pad part PP may apply the preliminary display device DD_I (see FIG. 4) with the coating solution CT, and the support part MD may move the pad part PP. In an embodiment, for example, the pad part PP may be in contact with the coating solution CT and may apply the pad part PP with the coating solution CT, and the support part MD may move the pad part PP to be adjacent to the preliminary display device DD_I, and thus the coating solution CT applied onto the pad part PP may be printed onto the preliminary display device DD_I. That is, the pad printing may be a method for applying a body to be applied body by indirectly transferring the coating solution CT using the pad part PP.

The pad part PP may include silicone. Since the pad part PP includes silicone, the pad part PP may have elastic features, and printing and/or applying may be possible even on a thing which is not flat using the elastic features of the pad part PP. Accordingly, the coating device PMa may fill, with the coating solution CT, the step region HA defined by the side surface S_DP of the display panel DP (or the side surface of the optical film OL) and the side surface S_WM of the window module WM (or the side surface of the second adhesive layer AL2).

The coating device PMa may apply the side surface of the preliminary display device DD_I. In an embodiment, for example, while moving in an opposite direction of the third direction DR3, the coating device PMa may apply from the side surface S_DP of the display panel DP to the side surface S_WM of the window module WM. However, this is an example, and an embodiment of the invention is not limited thereto. In an embodiment, for example, while moving in the third direction DR3, the coating device PMa may apply from the side surface S_WM of the window module WM to the side surface of the display panel DP.

Referring to FIG. 5C, an embodiment of the operation of filling with the coating solution CT may include performing an electro-hydro-dynamic printing. When an electric field formed by the coating device PMb exceeds a critical value, a stress caused by repulsion of surface charges of the coating solution CT in the coating device PMb may exceed a surface tension, and thus the coating solution CT may be emitted toward a target body to be applied.

The coating device PMb may apply a side surface of the preliminary display device DD_I (see FIG. 4). In an embodiment, for example, while moving in an opposite direction of the third direction DR3, the coating device PMb may apply from the side surface S_DP of the display panel DP to the side surface S_WM of the window module WM. However, this is an example, and an embodiment of the invention is not limited thereto. In an embodiment, for example, while moving in the third direction DR3, the coating device PMb may apply from the side surface S_WM of the window module WM to the side surface of the display panel DP.

However, the operation of applying the side surface of the preliminary display device DD_I is not limited to the embodiments in FIGS. 5A to 5C. In an embodiment, for example, the side surface of the preliminary display device DD_I may be applied in a pneumatic printing method. In addition, FIGS. 5A to 5C illustrate embodiments where the side surface of the preliminary display device DD_I is applied once, but an embodiment of the invention is not limited thereto, and the side surface of the preliminary display device DD_I may be applied multiple times.

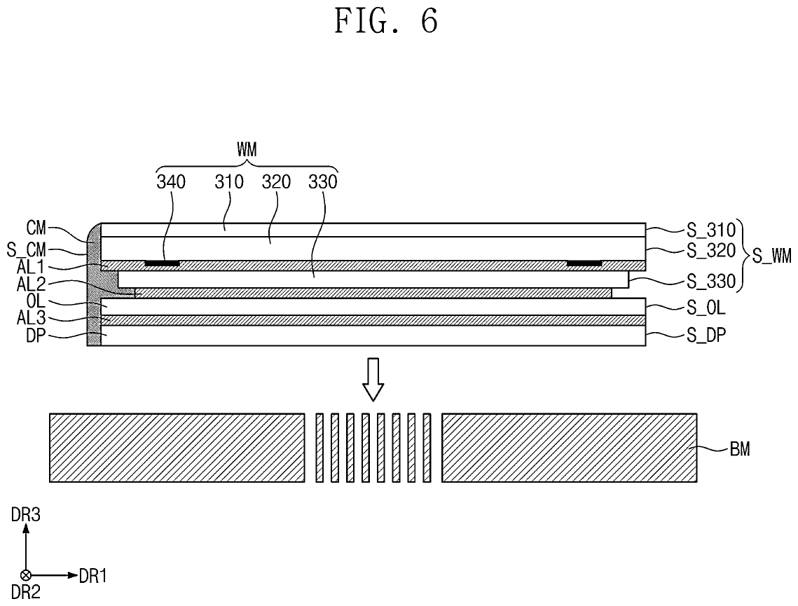

Thereafter, referring to FIG. 6, the method for manufacturing a display device according to an embodiment of the invention may include the operation of coupling the preliminary display device DD_I and the lower substrate BM. In an embodiment, for example, the preliminary display device DD_I in which the coating member CM is formed may move in an opposite direction of the third direction DR3, and be coupled to the lower substrate BM. However, this is an example, and an embodiment of the invention is not limited thereto. In an embodiment, for example, the lower substrate BM may move in the third direction DR3 and be coupled to the preliminary display device DD_I in which the coating member CM is formed, or the preliminary display device DD_I, in which the coating member CM is formed, and the lower substrate BM may simultaneously move and be coupled to each other. The lower substrate BM and the preliminary display device DD_I may be coupled by the fourth adhesive layer AL4 (see FIG. 2), and thus the display device DD (see FIG. 2) may be formed.

According to embodiments of the invention, as described above, a step formed on a side surface of a display device may be compensated by partially applying a coating member onto the side surface of the display device. In such embodiments, adhesion between a window module, an optical film, and a display panel which constitute the display device may be improved, foreign matters may be blocked from being introduced inside the display device, and anti-scratch characteristics and impact resistance characteristics of the display device may be improved.

In embodiments, since the coating member includes a leather section finishing material, flexibility of the coating member may be improved, and thus even when folding of the display device is repeated, separation of the coating member from a side surface of the display device may be reduced or removed, and a discolor phenomenon of the side surface of the display device DD may be reduced or removed.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel in which a first region, a second region, and a third region are defined along a first direction;
a window module disposed on the display panel, and including a window substrate;
a coating member covering a side surface of the display panel and a side surface of the window module; and
a lower substrate disposed under the display panel,
wherein a side surface of the window substrate is disposed more inwardly than the side surface of the display panel is, and
a side surface of the coating member is connected to the lower substrate.

2. The display device of claim 1, wherein the coating member comprises a resin material and a plurality of particles.

3. The display device of claim 2, wherein the resin material comprises urethane.

4. The display device of claim 2, wherein the resin material comprises acrylic.

5. The display device of claim 1, wherein the display panel comprises a first side surface, a second side surface, a third side surface, and a fourth side surface,
the first side surface, the second side surface, and the fourth side surface are coupled to the coating member, and
a region adjacent to the third side surface is bent.

6. The display device of claim 5, wherein the first side surface and the third side surface are spaced apart from each other in the first direction and extend in a second direction crossing the first direction, and
the second side surface and the fourth side surface are spaced apart from each other in the second direction and extend in the first direction.

7. The display device of claim 1, wherein a step region defined by the side surface of the display panel and the side surface of the window module is filled with the coating member.

8. The display device of claim 1, wherein the window module further comprises a window protection layer, a light-blocking pattern, and a functional layer.

9. A display device comprising:
a display panel;
a window module disposed on the display panel;
a coating member which fills a step region defined by a side surface of the display panel and a side surface of the window module; and
a lower substrate disposed under the display panel.

10. The display device of claim 9, wherein the coating member covers the side surface of the display panel and the side surface of the window module.

11. The display device of claim 9, wherein a first region, a second region, and a third region are defined in the display panel along a first direction,
the side surface of the window module is disposed more inwardly than the side surface of the display panel is, and
a side surface of the coating member is connected to the lower substrate.

12. The display device of claim 11, wherein the display panel comprises:
a first side surface extending in a second direction crossing the first direction;
a second side surface extending from the first side surface in the first direction;
a third side surface extending from the second side surface in a direction parallel to the second direction; and
a fourth side surface extending from the third side surface in a direction parallel to the first direction,
the first side surface, the second side surface, and the fourth side surface are coupled to the coating member, and
a region adjacent to the third side surface is bent.

13. The display device of claim 9, wherein the coating member comprises a resin material and a plurality of particles.

14. The display device of claim 13, wherein the resin material comprises at least one selected from urethane and acrylic.

15. A method for manufacturing a display device, the method comprising:
preparing a preliminary display device including a display panel and a window module;
filling, with a coating solution, a step region defined by a side surface of the display panel and a side surface of the window module; and
coupling the preliminary display device to a lower substrate.

16. The method of claim 15, wherein the display panel comprises:
a first side surface extending in s second direction crossing a first direction;
a second side surface extending from the first side surface in the first direction;
a third side surface extending from the second side surface in a direction parallel to the second direction; and
a fourth side surface extending from the third side surface in a direction parallel to the first direction, and
the filling the step region with the coating solution comprises applying a coating member to be in contact with the first side surface, the second side surface, and the fourth side surface of the display panel.

17. The method of claim 15, wherein the coating solution comprises a resin material and a plurality of particles, and
the resin material comprises at least one selected from urethane and acrylic.

18. The method of claim 15, wherein the filling the step region with the coating solution comprises performing a gravure coating.

19. The method of claim 15, wherein the filling the step region with the coating solution comprises performing a pad printing.

20. The method of claim 15, wherein the filling the step region with the coating solution comprises performing an electro-hydro-dynamic printing.
